(19) United States
(12) Patent Application Publication
(10) Pub. No.: US 2026/0129995 A1
(43) Pub. Date: May 7, 2026

(54) INTEGRATED CIRCUIT DEVICE AND MANUFACTURING METHOD THEREOF

(71) Applicant: Taiwan Semiconductor Manufacturing Company, Ltd., Hsinchu (TW)

(72) Inventors: Min-Feng Kao, Chiayi City (TW); Jen-Cheng Liu, Hsin-Chu City (TW); Hsiu-Yun Yeh, Taoyuan City (TW)

(73) Assignee: Taiwan Semiconductor Manufacturing Company, Ltd., Hsinchu (TW)

(21) Appl. No.: 18/938,255

(22) Filed: Nov. 5, 2024

(51) Int. Cl. H01L 27/146

(52) U.S. Cl. CPC H10F 39/809; H10F 39/018; H10F 39/811

(57) ABSTRACT

A device includes a first tier which includes a first substrate, a first device disposed at a side of the first substrate, a first isolation structure surrounding the first device, a second isolation structure disposed between the first isolation structure and a sidewall of the first substrate, a through substrate via (TSV) extending between the side and an opposing side of the first substrate, and a first bonding structure disposed over the side of the first substrate and electrically coupled to the first device. The TSV is laterally separated from the first isolation structure by the second isolation structure.

### BACKGROUND

Many modern-day electronic devices (e.g., smartphones, digital cameras, biomedical imaging devices, automotive imaging devices, etc.) include image sensors. The image sensors include one or more photodetectors configured to absorb incident radiation and output electrical signals corresponding to the incident radiation. Image sensors may include stacked dies to decrease a footprint of each pixel and increase device density.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view illustrating a first integrated circuit (IC) tier, in accordance with some embodiments.

FIGS. 2A-2C are schematic cross-sectional views of various stages of a second IC tier, in accordance with some embodiments.

FIGS. 3A-3D are schematic cross-sectional views of variations of a second IC tier, in accordance with some embodiments.

FIG. 4 is a schematic cross-sectional view illustrating a third IC tier, in accordance with some embodiments.

FIG. 5 is a schematic cross-sectional view illustrating a bonded structure including the first IC tier, the second IC tier, and the third IC tier, in accordance with some embodiments.

FIG. 6 is a schematic cross-sectional view illustrating a stacked IC device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Formation of 3-dimensional IC (3DIC) by using through substrate vias (TSVs) to facilitate die stacking has contributed to the increase in integration density. However, the implementation of the TSVs to form 3DIC may cause stress being distributed on active regions near the TSVs during the fabrication process, thereby affecting the performance of active devices. It is important to reduce the effect of the TSVs on neighboring active devices. Embodiments will be described with respect to specific embodiments in which a stacked IC device may include multiple IC tiers stacked upon and bonded to one another. The TSVs in the middle IC tier of the stacked IC device may penetrate through an isolation structure and/or be laterally surrounded by an isolation structure. The isolation structure associated with the TSVs may function as a stress-relief structure, thereby reducing the stress on the adjacent active devices. The stacked IC device may be implemented as a complementary metal-oxide semiconductor (CMOS) image sensor device, a memory device (e.g., a high bandwidth memory (HBM) cube or the like), etc. However, the embodiments illustrated herein are only intended to be illustrative of the embodiments and are not intended to limiting. Rather, the ideas presented herein may be incorporated into a wide variety of embodiments, and all such embodiments are fully intended to be included within the scope of the embodiments.

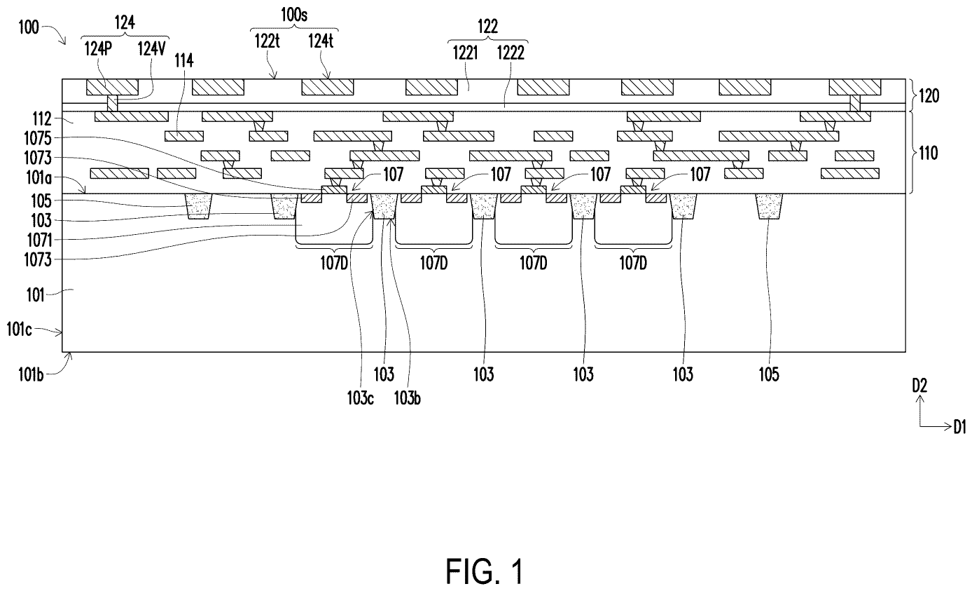

FIG. 1 is a schematic cross-sectional view illustrating a first IC tier 100, in accordance with some embodiments. Referring to FIG. 1, the first IC tier 100 includes a first substrate 101 including a first side 101a, a second side 101b opposite to the first side 101a, and a sidewall 101c connected to the first side 101a and the second side 101b, first isolation structures 103 formed in the first substrate 101, at least one second isolation structure 105 formed in the first substrate 101 and disposed alongside the array of the first isolation structures 103, first device regions 107D included in and/or on the first substrate 101 and enclosed by the first isolation structures 103, first devices 107 formed in the first device regions 107D, a first interconnect structure 110 formed over the first side 101a of the first substrate 101 and electrically coupled to the first devices 107, and a front-side bonding structure 120 formed over the first interconnect structure 110 and electrically coupled to the first devices 107 through the first interconnect structure 110.

The first substrate 101 may include silicon (e.g., a silicon substrate), a material including silicon, an III-V compound semiconductor material such as gallium arsenide, a semiconductor-on-insulator (SOI), or another type of semiconductor material. The first isolation structures 103 formed in the first substrate 101 may extend from the first side 101a toward the second side 101b. In some embodiments, the first isolation structures 103 and the second isolation structures 105 are referred to shallow trench isolation (STI) structures. The first isolation structures 103 and the second isolation structures 105 may include one or more dielectric materials, such as a silicon oxide, a silicon nitride, and/or a silicon oxynitride, and/or the like. Each of the first isolation structures 103 may surround one of the first device region 107D to provide the electrically isolation for the first device 107 in the first substrate 101. The second isolation structures 105 may be disposed between the sidewall 101c of the first substrate 101 and the outermost ones of the first isolation structures 103 in the array of the first isolation structures 103. The second isolation structures 105 may be referred to as dummy isolation structures. In some embodiments, the first isolation structures 103 and the second isolation structures 105 are substantially identical, have the same material(s), and are formed by the same process.

With continued reference to FIG. 1, the first devices 107 may be formed in/on the first substrate 101 and within the first device regions 107D surrounded by the first isolation structures 103. The first devices 107 may be or include one or more application-specific integrated circuit (ASIC) devices, one or more system-on-chip (SOC) devices, one or more active devices (e.g., transistors, diodes and/or the like), and/or one or more passive devices (e.g., capacitors, inductors, resistors, and/or the like). In some embodiments, at least a portion of the first devices 107 is implemented as transistors (e.g., MOSFETs, FinFETs, GAA-FETs, nanosheet field-effect transistors, the like, or any combination of the foregoing). In some embodiments, a doping well 1071 is disposed in the first device region 107D of the first substrate 101 and underlies the first isolation structures 103. The doping well 1071 may extend continuously from/to opposite sides of the first device region 107D. For example, the doping well 1071 extends downwardly to a position lower than a bottom surface 103b of the first isolation structure 103, and the doping well 1071 may be formed contacting an inner sidewall 103c of the first isolation structure 103. The doping well 1071 may be an upper region of the first substrate 101 with a p-type (or n-type) doping. For example, the doping well 1071 has a doping type opposite to that of the adjoining regions of the first substrate 101, or the adjoining regions of the first substrate 101 are intrinsic.

In some embodiments where the first devices 107 are implemented as the transistors, a pair of source/drain (S/D) regions 1073 is disposed in the respective first device region 107D and laterally spaced one from another in a first direction D1 (e.g., the X-direction or the Y-direction), a gate structure 1075 is arranged between the pair of S/D regions 1073 and overlying the first side 101a of the first substrate 101 in a second direction D2 (e.g., the Z-direction), where the first direction D1 and the second direction D2 may be substantially perpendicular to each other. For example, the S/D regions 1073 and the doping well 1071 are doped regions having opposite doping types. The respective first device 107 (represented by the transistor) may further include a channel region (not individually labeled) which is defined functionally as a region of the first device region 107D laterally between the S/D regions 1073 and underneath the gate structure 1075. In some embodiments, the S/D regions 1073 and the channel region are in the doping well 1071. In some embodiments, the S/D regions 1073 and the channel region are doped regions of the first substrate 101 having opposite doping types. For example, the channel region is doped with the p-type dopants and the S/D regions 1073 are doped with the n-type dopants, or vice versa. The channel region may be a selective conductor that allows current flowing from one of the S/D regions 1073 to another one of the S/D regions 1073 when sufficient biases are applied on the gate structure 1075 and the S/D regions 1073.

With continued reference to FIG. 1, the first interconnect structure 110 may include one or more dielectric layer(s) 112 and conductive patterns 114 formed in the dielectric layers 112. The dielectric layers 112 may be or include silicon oxide, a low-k dielectric material, an extreme low-k dielectric material, some other dielectric material, or any combination of the foregoing. The conductive patterns 114 may include conductive vias, conductive pads, and conductive lines, and may be formed of one or more conductive material(s) such as copper, aluminum, titanium nitride, tantalum nitride, tungsten, ruthenium, some other conductive material, or any combination of the foregoing. For example, the bottommost ones of the conductive vias of the conductive patterns 114 are in physical and electrically contact with the first devices 107.

Still referring to FIG. 1, the front-side bonding structure 120 may include one or more bonding dielectric layer(s) 122 and bonding conductors 124 embedded in the dielectric layer 122. In some embodiments, the bonding dielectric layer 122 includes an upper layer 1221 and a lower layer 1222 vertically separating the upper layer 1221 from the dielectric layers 112. For example, the lower layer 1222 is an etch stop layer having a different material than the upper layer 1221. The bonding conductors 124 may be or include conductive pads, conductive vias, a combination thereof, etc. For example, the via portion 124V of the respective bonding conductor 124 penetrates through the lower layer 1222 to land on the topmost one of the conductive patterns 114, and the pad portion 124P of the respective bonding conductor 124 overlies the via portion 124V. The via portion 124V and the pad portion 124P may be laterally covered by the bonding dielectric layers 122. However, the bonding conductors 124 may have a different shape/configuration than shown. For example, the top surfaces 124t of the bonding conductors 124 are substantially leveled (or coplanar) with the top surfaces 122t of the bonding dielectric layer 122, within process variations. The top surfaces 124t of the bonding conductors 124 and the top surfaces 122t of the bonding dielectric layer 122 may be collectively viewed as a bonding surface 100s of the first IC tier 100. The bonding surface 100s may be substantially flat. The above examples of the first IC tier 100 are provided for illustrative purposes only, and other embodiments may utilize fewer or additional elements.

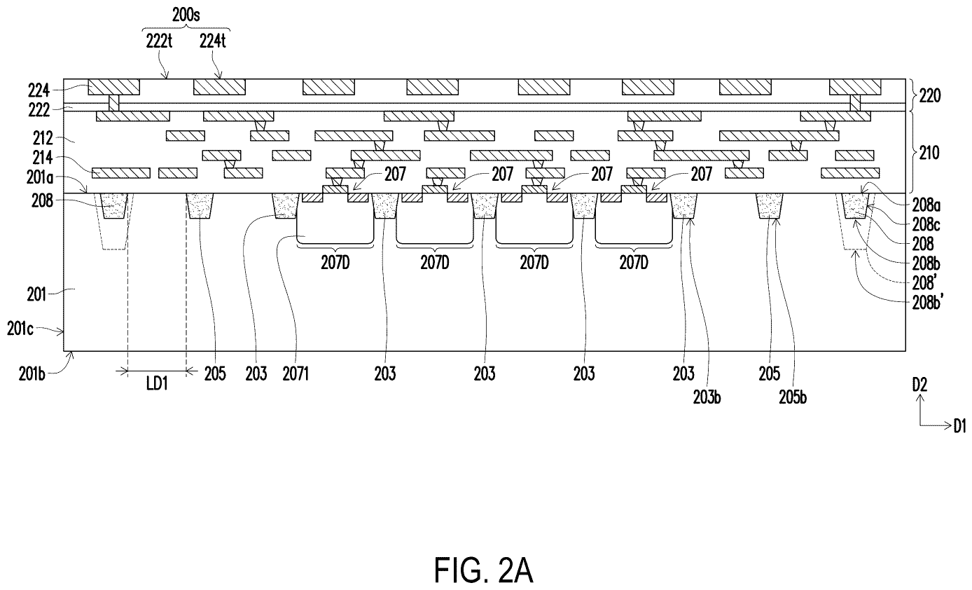

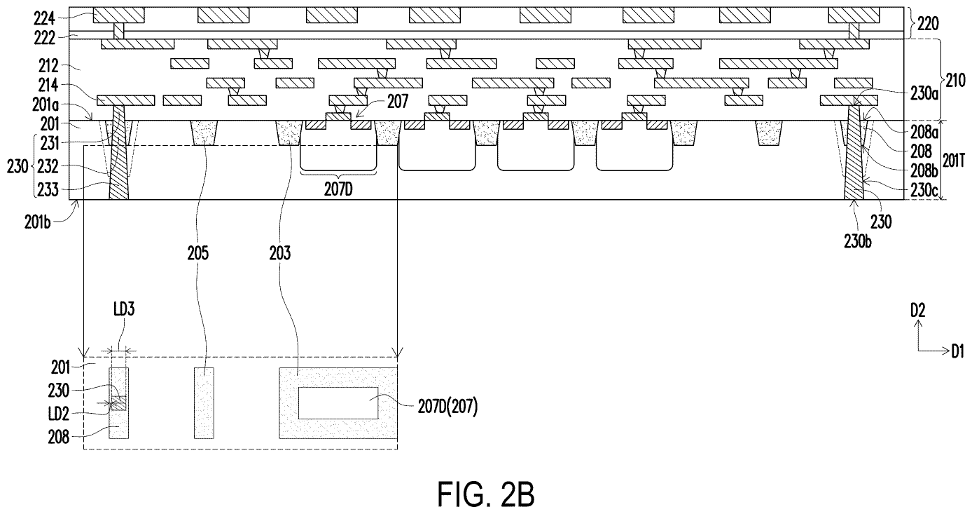

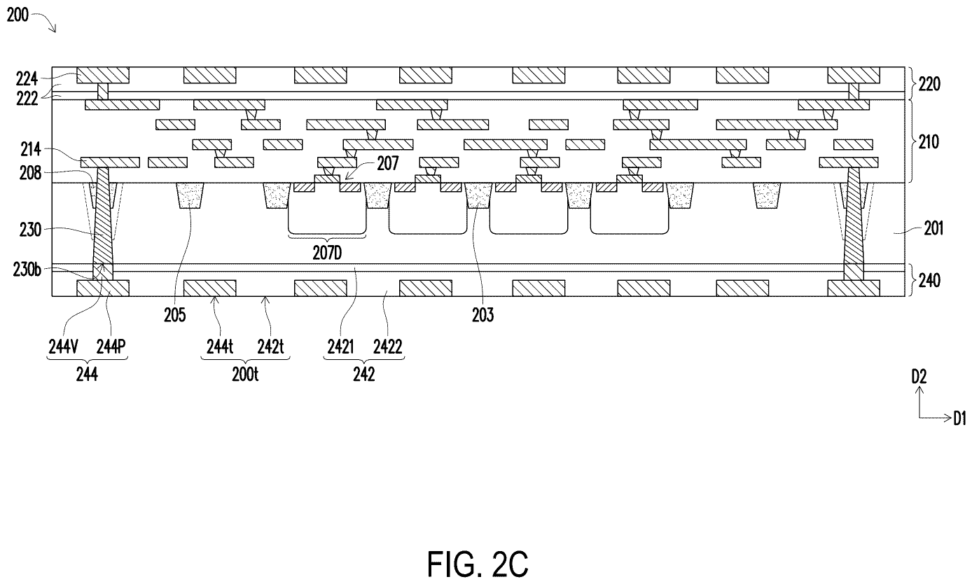

FIGS. 2A-2C are schematic cross-sectional views of various stages of a second IC tier 200, in accordance with some embodiments. Unless specified otherwise, like reference numerals represent like components in the embodiment shown in FIG. 1. Referring to FIG. 2A and with reference to FIG. 1, the structure shown in FIG. 2A may be similar to the first IC tier 100, and thus the detailed descriptions are not repeated for the sake of brevity. For example, a second substrate 201 includes a first side 201a, a second side 201b opposite to the first side 201a, and a sidewall 201c connected to the first side 201a and the second side 201b. First isolation structures 203 and at least one second isolation structure 205 may be formed in the second substrate 201. In alternative embodiments, the second isolation structure 205 is omitted. The second substrate 201, the first isolation structures 203, and the second isolation structures 205 may be similar to the first substrate 101, the first isolation structures 103, and the second isolation structures 105, respectively.

In some embodiments, at least one third isolation structure 208 is formed in the second substrate 201 and extends form the first side 201a toward the second side 201b. The second isolation structures 205 may be disposed between the first isolation structures 203 and the third isolation structures 208. For example, the respective third isolation structure 208 is disposed between the sidewall 201c of the second substrate 201 and the nearest one of the second isolation structures 205. The respective third isolation structure 208 may be laterally separated from the nearest one of the second isolation structures 205 by a non-zero distance LD1 in the first direction D1. In some embodiments, the second isolation structures 205 and the third isolation structures 208 are substantially identical, have the same material(s), and are formed by the same process. The second isolation structures 205 and the first isolation structures 203 may be substantially identical, have the same material(s), and are formed by the same process. In some embodiments, the first isolation structures 203, the second isolation structure 205, and the third isolation structures 208 are tapered from the first side 201a toward the second side 201b of the second substrate 201. For example, the respective third isolation structure 208 includes a first side 208a, a second side 208b opposite to the first side 208a and narrower than the first side 208a, and a slanted sidewall 208c connected to the first side 208a and the second side 208b.

In alternative embodiments, the second isolation structures 205 and the third isolation structures 208′ (outlined in the dashed lines) are made of different materials and/or formed at different steps. The top-view shapes and/or the cross-sectional profiles of the third isolation structures 208′ may be different from those of the second isolation structures 205 according to some alternative embodiments. For example, the respective third isolation structures 208′ extends further than the first isolation structures 203 or the second isolation structure 205. The respective third isolation structure 208′ may extend downwardly to a position lower than a bottom surface of the adjacent first isolation structure 203 or the second isolation structure 205. In some embodiments, the respective third isolation structure 208′ extends further than a bottom of a doping well 2071. For example, the respective third isolation structure 208′ includes the first side 208a and a second side 208b′ opposite to the first side 208a, and the second side 208b′ is between the second side 201b of the second substrate 201 and the bottom surface 205b of the adjacent second isolation structure 205 (or the bottom surface 203b of the adjacent first isolation structure 203).

With continued reference to FIG. 2A and FIG. 1, second device regions 207D may be formed in and/or on the second substrate 201 and enclosed by the second isolation structures 203. The second devices 207 may be formed in the second device regions 207D. In some embodiments, the doping well 2071 of the respective second device 207 is formed in the second device region 207D and underlies the first isolation structures 203. A second interconnect structure 210 including one or more dielectric layer(s) 212 and conductive patterns 214 formed in the dielectric layers 212 may be formed over the first side 201a of the second substrate 201 and electrically coupled to the second devices 207. In some embodiments, at least a portion of the second devices 207 is implemented as transistors (e.g., reset transistors, source-follower transistors, select transistors, and/or the like). A front-side bonding structure 220 including one or more bonding dielectric layer(s) 222 and bonding conductors 224 formed in the dielectric layer 222 may be formed over the second interconnect structure 210 and electrically coupled to the second devices 207 through the second interconnect structure 210. The second device regions 207D, the second devices 207, the doping well 2071, the second interconnect structure 210, and the front-side bonding structure 220 may be similar to the first device regions 107D, the first devices 107, the doping well 1071, the first interconnect structure 110, and the front-side bonding structure 120, respectively. The top surfaces 224t of the bonding conductors 224 and the top surface 222t of the bonding dielectric layer 222 may be collectively viewed as a front-side bonding surface 200s of the second IC tier (“200” labeled in FIG. 2C). The front-side bonding surface 200s may be substantially flat.

Referring to FIG. 2B and with reference to FIG. 2A, the second substrate 201 may be thinned by a backside thinning process. For example, the backside thinning process includes a chemical mechanical planarization (CMP) process, a grinding process, an etching process, a combination thereof, etc. The backside thinning process may be performed on the second side 201b of the second substrate 201 until the second substrate 201 have a thinned thickness 201T. In alternative embodiments where the second substrate 201 is thin enough, the backside thinning process is skipped. Next, at least one through substrate via (TSV) 230 may be formed in the second substrate 201 and pass through the corresponding third isolation structure 208. The TSVs 230 may include one or more conductive materials (e.g., cobalt, titanium, tungsten, copper, aluminum, tantalum, titanium nitride, tantalum nitride, gold, silver, metal alloy, combinations thereof, etc.). For example, the respective TSV 230 includes a seed layer, a dielectric liner separating the second substrate 201 from the seed layer, and a metallic layer plated on the seed layer.

In some embodiments, the respective TSV 230 extends continuously between the first side 201a and the second side 201b of the second substrate 201 and may extend further into the dielectric layers 212 of the second interconnect structure 210 to be electrically coupled to the conductive patterns 214. In some embodiments, the respective TSV 230 passes through the second side 208b and the first side 208a of the corresponding third isolation structure 208 and extends into the dielectric layers 212 of the second interconnect structure 210. The respective TSV 230 may include a first side 230a physically connected to one of the conductive patterns 214, a second side 230b opposite to the first side 230a, and a slanted sidewall 230c connected to the first side 230a and the second side 230b. For example, a planarization process (e.g., CMP, grinding, etching, a combination thereof, etc.) is performed so that the second side 230b of the respective TSV 230 is substantially leveled (or coplanar) with the second side 201b of the second substrate 201, within process variations. The respective TSV 230 may be tapered from the second side 230b toward the first side 230a. For example, the first side 230a is narrower than the second side 230b. The tapering direction of the respective TSV 230 may be opposite to the tapering direction of the corresponding third isolation structure 208. The respective TSV 230 may be longer than the corresponding third isolation structure 208 in the second direction D2.

With continued reference to FIG. 2B, the respective TSV 230 may include a first portion 231 in lateral contact with the dielectric layers 212 of the second interconnect structure 210, a second portion 232 connected to the first portion 231 and in lateral contact with the third isolation structure 208, and a third portion 233 connected to the second portion 232 and in lateral contact with the second substrate 201. For example, the maximum width of the first portion 231 is less than the maximum width of the second portion 232, and the maximum width of the second portion 232 is less than the maximum width of the third portion 233. The length of the second portion 232 measured in the second direction D2 may depend on the depth of the third isolation structure 208, and the depth of the third isolation structure 208 is less than the thinned thickness 201T of the second substrate 201.

The enlarged top view outlined in the dashed box of FIG. 2B shows the configuration of the third isolation structure 208, the TSV 230 disposed in the third isolation structure 208, the second isolation structure 205 laterally spaced apart from the third isolation structure 208, and the first isolation structure 203 laterally spaced apart from the second isolation structure 205. For example, the third isolation structure 208, the second isolation structure 205, and the first isolation structure 203 are sequentially arranged along the first direction D1. In some embodiments, the first isolation structure 203 forms a close loop in the top view. The second device region 207D in which the second device 207 is formed may be encircled by the first isolation structure 203. The second isolation structure 205 may form as a strip in the top view and may be disposed between the first isolation structure 203 and the third isolation structure 208. Alternatively, the second isolation structure 205 is omitted.

With continued reference to the enlarged top view in the dashed box of FIG. 2B, the third isolation structure 208 may form as a strip as the second isolation structure 205, and the TSV 230 may be immediately surrounded by the third isolation structure 208, as shown in the top view. In some embodiments, the minimum thickness LD2 of the third isolation structure 208 formed on the sidewall 230c of the TSV 230 is less than the lateral dimension LD3 of the TSV 230. A ratio of the minimum thickness LD2 to the lateral dimension LD3 may be less than 0.5, e.g., substantially equal to about 0.3. Although in the enlarged top view of FIG. 2B, the TSV 230 has a square/rectangular top-view shape and the second and third isolation structures have a strip top-view shape; the TSV 230, the second isolation structure 205, and the third isolation structure 208 may have a different top-view shape (e.g., a circular shape, an oval shape, a polygonal shape, an irregular shape, etc.) than shown.

Referring to FIG. 2C and with reference to FIG. 2B, a backside bonding structure 240 may be formed on the second side 201b of the second substrate 201 and coupled to the second side 230b of the respective TSV 230. The backside bonding structure 240 may include one or more bonding dielectric layer(s) 242 and bonding conductors 244 formed in the dielectric layer 242. The bonding conductors 244 may be electrically coupled to the second devices 207 through the TSVs 230 and the conductive patterns 214 of the second interconnect structure 210. The bonding conductors 244 may be electrically coupled to the bonding conductors 224 of the front-side bonding structure 220 through the TSVs 230 and the conductive patterns 214 of the second interconnect structure 210. In some embodiments, the bonding dielectric layer 242 includes an upper layer 2421 and a lower layer 2422, where the upper layer 2421 vertically separates the lower layer 2422 from the second substrate 201. For example, the upper layer 2421 is an etch stop layer having a different material than the lower layer 2422.

The bonding conductors 244 may be or include conductive pads, conductive vias, a combination thereof, etc. For example, the via portion 244V of the respective bonding conductor 244 penetrates through the upper layer 2421 to land on the second side 230b of the corresponding TSV 230, and the pad portion 244P of the respective bonding conductor 244 underlies and is connected to the via portion 244V. The via portion 244V and the pad portion 244P may be laterally covered by the bonding dielectric layers 242. However, the bonding conductors 244 may have a different cross-sectional profile/configuration than shown. For example, an outermost surfaces 244t of the bonding conductors 244 facing away the second substrate 201 are substantially leveled (or coplanar) with an outermost surface 242t of the bonding dielectric layer 242, within process variations. The outermost surfaces 244t of the bonding conductors 244 and the outermost surface 242t of the bonding dielectric layer 242 may be collectively viewed as a backside bonding surface 200t of the second IC tier 200. The backside bonding surface 200t of the second IC tier 200 may be substantially flat. The above examples of the second IC tier 200 are provided for illustrative purposes only, and other embodiments may utilize fewer or additional elements.

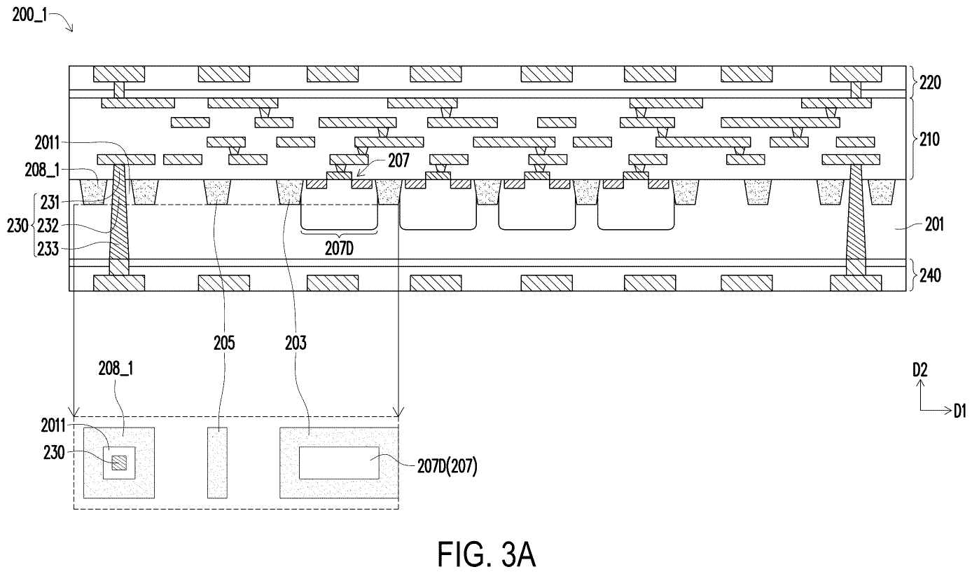

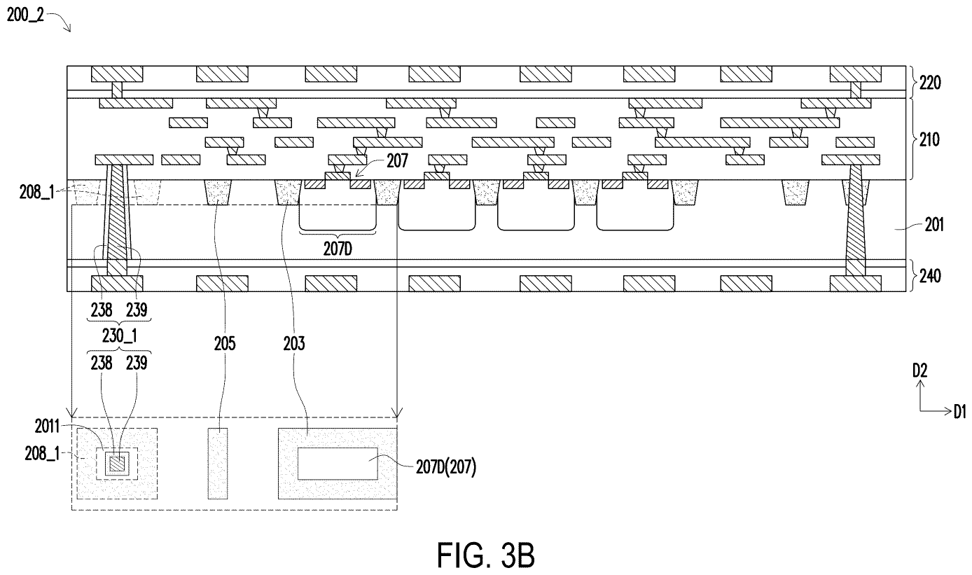

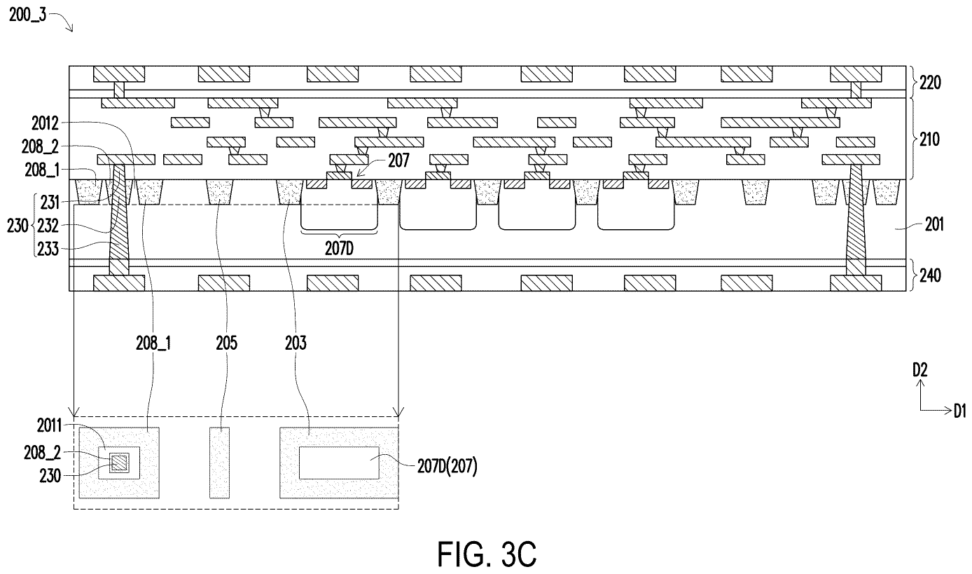

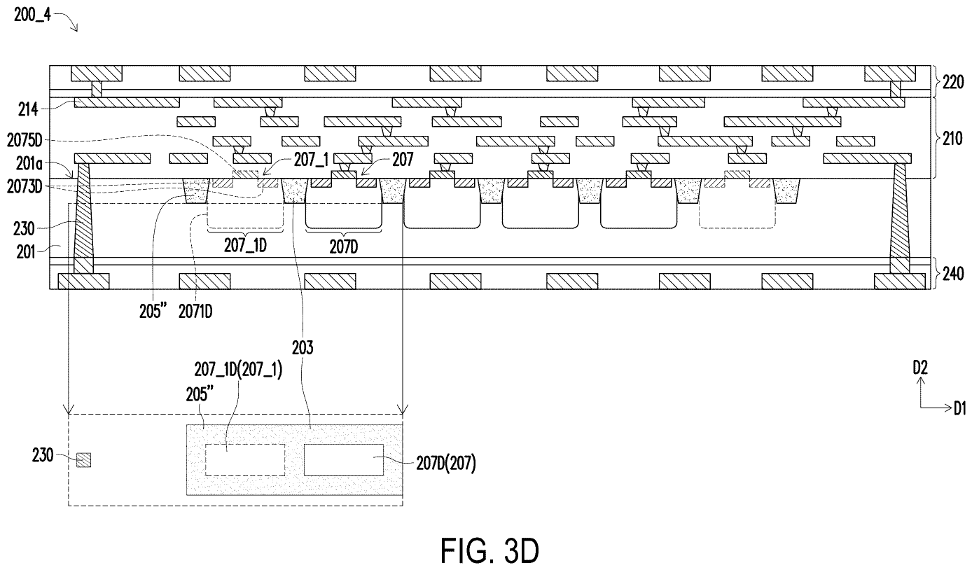

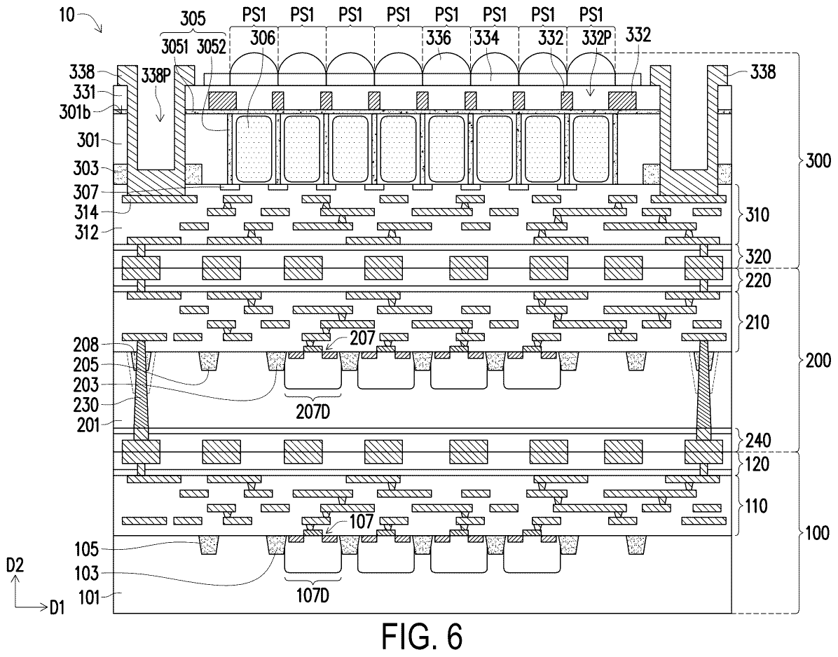

It has been found that the performance of devices in the vicinity of the respective TSV may suffer due to the stress induced by the TSV. This stress may arise from the fabrication process of the TSV or due to mismatch in coefficient of thermal expansion (CTE) between the TSV and the substrate when the IC tier undergoes a temperature change during thermal processes. One of the approaches for reducing the impact of stress on the performance of the second IC tier is to impose a keep-out-zone (KOZ) around the TSV and active devices are restricted from being placed within the KOZ. However, when the size of the KOZ is not enough (or too small), the performance of devices in the vicinity of the respective TSV may still suffer and the stress induced by the TSV may cause shifts of the device performance. To help release the stress and thereby prevent the shifts of the device performance, the third isolation structure 208 may be formed at a periphery region of the second IC tier 200 and laterally spaced apart from the second device region 207D and the TSV 230 may penetrate through the third isolation structure 208. In this manner, the stress induced by the TSV may be absorbed by the third isolation structure 208, and the impact of stress on the performance of devices may be minimized. As a result, the reliability of the second IC tier 200 may be improved. The third isolation structure 208 may be formed at the first and/or second isolation structure(s) formation stage, thus the formation of the third isolation structure 208 may be compatible with the CMOS fabrication process and may require no additional processes and masks. The second IC tier 200 may be implemented as a part of an image sensor device (e.g., a stacked IC device 10 shown in FIG. 6), a memory device (e.g., a high bandwidth memory (HBM) cube or the like; not shown), etc. There are some alternative implementations for reducing the impact of stress on the performance of the second IC tier as will be described later in accompanying with FIGS. 3A-3D.

FIGS. 3A-3D are schematic cross-sectional views of variations of a second IC tier, in accordance with some embodiments. Unless specified otherwise, like reference numerals represent like components in the embodiment shown in FIG. 2C. Referring to FIG. 3A and with reference to FIGS. 2B-2C, a second IC tier 200_1 shown in FIG. 3A may be similar to the second IC tier 200 shown in FIG. 2C, and thus the detailed descriptions are not repeated for the sake of brevity. The differences between the second IC tiers (200_1 and 200) may include that the third isolation structure 208_1 is formed as a close loop and the TSV 230 is formed within a region encircled by the third isolation structure 208_1. For example, the TSV 230 of the second IC tier 200_1 does not pass through the third isolation structure 208_1. In some embodiments, the second portion 232 of the respective TSV 230 of the second IC tier 200_1 connected to the first portion 231 and the third portion 233 is laterally surrounded by a portion 2011 of the second substrate 201 which is enclosed by the third isolation structure 208_1. The portion 2011 of the second substrate 201 may separate the third isolation structure 208_1 from the second portion 232 of the respective TSV 230.

In the cross-sectional view, the respective TSV 230 may be tapered in a direction from the third portion 233 toward the first portion 231, while the third isolation structure 208_1 may be tapered in a direction opposite to the tapering direction of the respective TSV 230. The portion 2011 of the second substrate 201 laterally between the third isolation structure 208_1 and the corresponding TSV 230 may be tapered in the direction substantially equal to the tapering direction of the respective TSV 230. For example, the lateral thickness of the portion 2011 of the second substrate 201 gradually increases in a direction from the second portion 232 toward the third portion 233. By configuring the TSV 230 laterally surrounded by the third isolation structure 208_1, the third isolation structure 208_1 may separate the TSV 230 from the second device region 207D, so that a sufficient distance is formed between the TSV 230 and the second device region 207D. The third isolation structure 208_1 may be used as a protective wall for protecting the second device 207 from stress induced by the TSV 230. As a result, the reliability of the second IC tier 200_1 may be improved.

Referring to FIG. 3B and with reference to FIGS. 3A, a second IC tier 200_2 shown in FIG. 3B may be similar to the second IC tier 200_1 shown in FIG. 3A, and thus the detailed descriptions are not repeated for the sake of brevity. The differences between the second IC tiers (200_2 and 200_1) lies in that the respective TSV 230_1 of the second IC tier 200_2 may include a dielectric liner 238 and a conductive layer 239 laterally covered by the dielectric liner 238, where the dielectric liner 238 separates the conductive layer 239 from the second substrate 201. The conductive layer 239 may include seed material and metallic material(s) such as copper, aluminum, titanium nitride, tantalum nitride, metal alloy, and/or the like. For example, the dielectric liner 238 functions as a stress-absorbing (or a buffer) layer. The dielectric liner 238 may be formed of one or more low-K or extra low-K (ELK) dielectric material(s) such as fluorinated silicate glass (FSG), carbon-containing dielectric materials, and may contain nitrogen, hydrogen, oxygen, and combinations thereof.

As shown in the top view, the dielectric liner 238 may encircle the conductive layer 239 so as to separate the conductive layer 239 from the portion 2011 of the second substrate 201. The dielectric liner 238 encircling the conductive layer 239 may contain a dielectric material that is different from the semiconductor material of the second substrate 201 and the conductive layer 238. The dielectric liner 238 acting as a stress-releasing layer may help to minimize the stress induced by the TSV 230_1 in the second IC tier 200_2. As a result, the reliability of the second IC tier 200_2 may be improved. In some embodiments, the third isolation structure 208_1 surrounding the corresponding TSV 230_1 is omitted. Therefore, the third isolation structures 208_1 are illustrated in the dashed lines to indicate they may or may not be included in the second substrate 201.

Referring to FIG. 3C and with reference to FIGS. 3A and 2C, a second IC tier 200_3 shown in FIG. 3C may be similar to the second IC tier 200_1 shown in FIG. 3A and the second IC tier 200 shown in FIG. 2C, and thus the detailed descriptions are not repeated for the sake of brevity. The differences between the second IC tiers (200_3 and 200_1) may include that the second IC tier 200_3 further includes at least one fourth isolation structure 208_2, the respective TSV 230 penetrates through the fourth isolation structure 208_2, and the respective TSV 230 and the fourth isolation structure 208_2 are encircled by the third isolation structure 208_1. For example, the second portion 232 of the respective TSV 230 connected to the first portion 231 and the third portion 233 is in lateral contact with the fourth isolation structure 208_2, similar to the TSV 230 of the second IC tier 200 described in FIG. 2B. The fourth isolation structure 208_2 may be laterally separated from the third isolation structure 208_1 by a portion 2012 of the second substrate 201. The third isolation structure 208_1 and the fourth isolation structure 208_2 may be formed of the same material(s) and/or may be formed during the same step. Alternatively, the third isolation structure 208_1 and the fourth isolation structure 208_2 are formed of different materials and/or may be formed by different steps.

In some embodiments, the fourth isolation structure 208_2 has a square/rectangular top-view shape. The second isolation structure 205′ may have a same/similar top-view shape as the fourth isolation structure 208_2. For example, the fourth isolation structure 208_2 and the second isolation structure 205′ are formed of the same/similar material(s) and may be formed at the same step. However, the fourth isolation structure 208_2 and the second isolation structure 205′ may have a different top-view shape (e.g., a circular shape, an oval shape, a polygonal shape, an irregular shape, etc.) than shown. By configuring the TSV 230 laterally surrounded by the third isolation structure 208_1, the third isolation structure 208_1 may be used as a protective wall to separate the TSV 230 from the second device region 207D for protecting the second device 207 from stress. The fourth isolation structure 208_2 laterally connected to the TSV 230 may also be able to reduce the stress induced by the TSV 230 in the second IC tier 200_3. As a result, the reliability of the second IC tier 200_3 may be improved.

Referring to FIG. 3D and with reference to FIG. 2C, a second IC tier 200_4 shown in FIG. 3D may be similar to the second IC tier 200 shown in FIG. 2C, and thus the detailed descriptions are not repeated for the sake of brevity. The differences between the second IC tiers (200_4 and 200) may include that the second IC tier 200_4 is free of the third isolation structure 208, the second IC tier 200_4 includes a dummy device 207_1 formed in a dummy device region 207_1D and between the outermost one of the second devices 207 and the respective TSV 230, and the dummy device region 207_1D is defined by the dummy isolation structure 205″. The respective TSV 230 may be laterally spaced apart from the dummy isolation structure 205″ in the first direction D1. For example, the dummy device region 207_1D and the dummy device 207_1 formed therein are similar to the second device region 207D and the second device 207 formed therein, except that the dummy device 207_1 is electrically floating in the second IC tier 200_4. For example, the dummy device 207_1 is electrically isolated from the adjacent second devices 207 by the dummy isolation structure 205″.

With continued reference to FIG. 3D, a dummy doping well 2071D may be disposed in the dummy device region 207_1D and underlies the dummy isolation structure 205″. The dummy doping well 2071D may extend continuously and respectively from and to opposite sides of the dummy device region 207_1D. The dummy doping well 2071D may be similar to the doping well 1071 described in FIG. 1, and thus the detailed descriptions are not repeated for the sake of brevity. In some embodiments, the dummy device 207_1 is implemented as a dummy transistor, where a pair of S/D regions 2073D is formed in the dummy device region 207_1D, and a gate structure 2075D is arranged between the pair of S/D regions 2073D and overlying the first side 201a of the second substrate 201 in the second direction D2. For example, the conductive patterns 214 of the second interconnect structure 210 are not in electrical contact with the gate structure 2075D and the S/D regions 2073D. That is, the dummy device 207_1 is not further connected to other metal lines. The conductive patterns 214 of the second interconnect structure 210 may be electrically isolated from the dummy device 207_1.

In some embodiment, the nearest second device region 207D is laterally separated from the TSV 230 by a overall distance of the dummy device region 207_1D and the dummy isolation structure 205″ measured in the first direction D1. The dummy device 207_1 interposed between the TSV 230 and the nearest second device region 207D in the first direction D1 may help to reduce the impact of stress on the performance of the second IC tier 200_4. The configuration of the dummy device 207_1 may increase the overall uniformity of distribution of second devices 207 in the second IC tier 200_4. As a result, the reliability of the second IC tier 200_4 may be improved. It should be appreciated that the second IC tier (e.g., 200_1, 200_2, 200_3, or 200_4) may be implemented as a part of an image sensor device (e.g., a stacked IC device 10 shown in FIG. 6), a memory device (e.g., a high bandwidth memory (HBM) cube or the like), or any suitable 3DIC device.

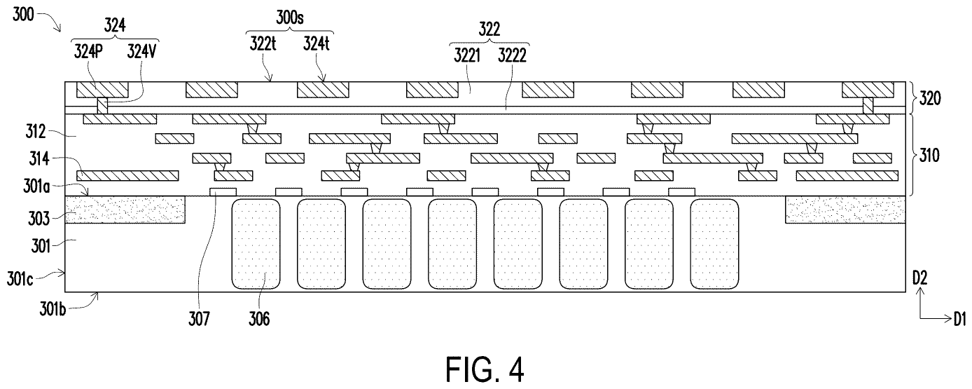

FIG. 4 is a schematic cross-sectional view illustrating a third IC tier 300, in accordance with some embodiments. Unless specified otherwise, like reference numerals represent like components in the embodiment shown in FIG. 1. Referring to FIG. 4, the third IC tier 300 may include a third substrate 301 including a first side 301a, a second side 301b opposite to the first side 301a, and a sidewall 301c connected to the first side 301a and the second side 301b. The material of the third substrate 301 may be similar to the first substrate 101 described in FIG. 1. In some embodiments, the third IC tier 300 includes first isolation structures 303 formed in the third substrate 301 at the first side 301a, image sensing elements 306 formed in the third substrate 301 and between the first side 301a and the second side 301b, and third devices 307 formed in/on the third substrate 301. For example, the respective third device 307 is formed at the first side 301a and overlies and/or is adjacent to the corresponding image sensing element 306. The image sensing elements 306 may be photodetectors, photodiodes, or doping regions formed by implantation process. The third devices 307 may be or include active devices (e.g., transistors, diodes, or the like), passive devices (e.g., capacitors, inductors, resistors, etc.), and/or one or more other components configured to measure the magnitude of a photocurrent to determine light intensity of incident light and/or to generate images and/or video. In some embodiments, at least a portion of the third devices 307 is implemented as transistors (e.g., transfer transistors for transferring accumulated charge from the image sensing elements 306, or the like), and the portion of the third devices 307 may selectively electrically couple the image sensing elements 306.

With continued reference to FIG. 4, the third IC tier 300 may include a third interconnect structure 310 formed over the first side 301a of the third substrate 301 and electrically coupled to the third devices 307, and a front-side bonding structure 320 formed over the third interconnect structure 310 and electrically coupled to the third interconnect structure 310. The third interconnect structure 310, similar to the first interconnect structure 110 described in FIG. 1, may include one or more dielectric layer(s) 312 and conductive patterns 314 formed in the dielectric layers 312, where the conductive patterns 314 are electrically coupled to the third devices 307. The front-side bonding structure 320, similar to the front-side bonding structure 120 described in FIG. 1, may include one or more bonding dielectric layer(s) 322 and bonding conductors 324 formed in the dielectric layer 322. In some embodiments, the bonding dielectric layer 322 includes an upper layer 3221 and a lower layer 3222 vertically separating the upper layer 3221 from the dielectric layers 312. For example, the lower layer 3222 is an etch stop layer having a different material than the upper layer 3221.

Still referring to FIG. 4, the bonding conductors 324 may be or include conductive pads, conductive vias, a combination thereof, etc. The via portion 324V of the respective bonding conductor 324 may penetrate through the lower layer 3222 to land on the topmost one of the conductive patterns 314, and the pad portion 324P of the respective bonding conductor 324 overlies and is connected to the via portion 324V. The via portion 324V and the pad portion 324P may be laterally covered by the bonding dielectric layers 322. However, the bonding conductors 324 may have a different shape/configuration than shown. The top surfaces 324t of the bonding conductors 324 are substantially leveled (or coplanar) with the top surface 322t of the bonding dielectric layer 322, within process variations. The top surfaces 324t of the bonding conductors 324 and the top surface 322t of the bonding dielectric layer 322 may be collectively viewed as a bonding surface 300s of the third IC tier 300. The bonding surface 300s may be substantially flat. The above examples of the third IC tier 300 are provided for illustrative purposes only, and other embodiments may utilize fewer or additional elements.

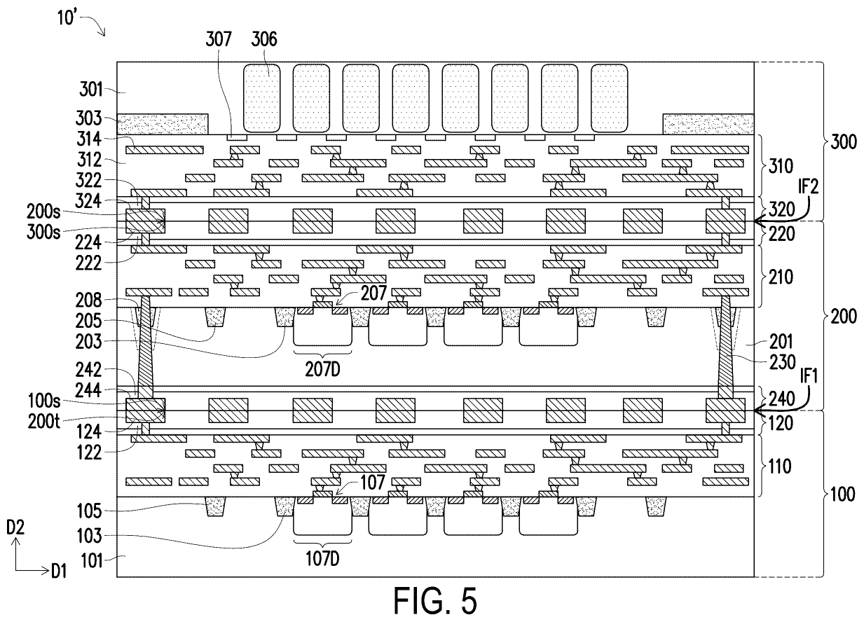

FIG. 5 is a schematic cross-sectional view illustrating a bonded structure 10′ including the first IC tier 100, the second IC tier 200, and the third IC tier 300, in accordance with some embodiments. Unless specified otherwise, like reference numerals represent like components in the embodiments shown in FIG. 1, FIG. 2C, and FIG. 4. Referring to FIG. 5 and with reference to FIGS. 1, 2C, and 4, the bonded structure 10′ may include the first IC tier 100, the second IC tier 200 stacked upon and bonded to the first IC tier 100, and the third IC tier 300 stacked upon and bonded to the second IC tier 200. For example, the front-side bonding structure 120 of the first IC tier 100 is bonded to the backside bonding structure 240 of the second IC tier 200, and the front-side bonding structure 220 of the second IC tier 200 is bonded to the front-side bonding structure 320 of the third IC tier 300. The bonding surface 100s of the first IC tier 100 may be bonded to the backside bonding surface 200t of the second IC tier 200, and the front-side bonding surface 200s of the second IC tier 200 may be bonded to the bonding surface 300s of the third IC tier 300. The bonding interface IF1 of the first IC tier 100 and the second IC tier 200 and the bonding interface IF2 of the second IC tier 200 and the third IC tier 300 may be substantially flat and planar.

With continued reference to FIG. 5, the bonding dielectric layer 122 of the first IC tier 100 may be fused to the bonding dielectric layer 242 of the second IC tier 200, and dielectric-to-dielectric bonds (e.g., oxide-to-oxide bonds) may be formed at the bonding interface IF1. The bonding conductors 124 of the first IC tier 100 may be bonded to the bonding conductors 244 of the second IC tier 200, and metal-to-metal bonds (e.g., copper-to-copper bonds) may be formed at the bonding interface IF1. The bonding dielectric layer 222 of the second IC tier 200 may be fused to the bonding dielectric layer 322 of the third IC tier 300, and dielectric-to-dielectric bonds (e.g., oxide-to-oxide bonds) may be formed at the bonding interface IF2. The bonding conductors 224 of the second IC tier 200 may be bonded to the bonding conductors 324 of the third IC tier 300, and metal-to-metal bonds (e.g., copper-to-copper bonds) may be formed at the bonding interface IF2. It should be noted that the second IC tier 200 may be replaced with the second IC tiers (e.g., 200_1, 200_2, 200_3, 200_4, a combination thereof, etc.). The three-tier configuration of the bonded structure 10′ shown herein is an example. It should be appreciated that the bonded structure 10′ may have more than three IC tiers, where multiple second IC tiers (e.g., 200, 200_1, 200_2, 200_3, 200_4, a combination thereof, etc.) may be stacked upon one another and between the first IC tier 100 and the third IC tier 300.

FIG. 6 is a schematic cross-sectional view illustrating a stacked IC device 10, in accordance with some embodiments. Unless specified otherwise, like reference numerals represent like components in the embodiment shown in FIG. 5. Referring to FIG. 6 and with reference to FIG. 5, the bonded structure 10′ may be processed to form the stacked IC device 10. For example, the stacked IC device 10 includes a second isolation structure 305 formed in/on the third substrate 301. The second isolation structure 305 may be or include a dielectric material (e.g., silicon dioxide, silicon nitride, a metal oxide, etc.), a metal material (e.g., tungsten, aluminum, titanium nitride, etc.), some other suitable material, or any combination of the foregoing. For example, the second isolation structure 305 includes a first portion 3051 overlying the second side 301b of the third substrate 301 and second portions 3052 connected to the first portion 3051 and penetrating through the third substrate 301 toward the third devices 307. The second portions 3052 of the second isolation structure 305 may extend in the second direction D2 and isolate the image sensing elements 306 from one another. In some embodiments, the second portions 3052 of the second isolation structure 305 are configured as a deep trench isolation (DTI) structures.

With continued reference to FIG. 6, the stacked IC device 10 may include a dielectric layer 331 formed over the second side 301b of the third substrate 301 and a grid structure 332 embedded in the dielectric layer 331. For example, the dielectric layer 331 overlies the first portion 3051 of the second isolation structure 305. The dielectric layer 331 may include one or more passivation material(s) or any suitable dielectric material(s). The grid structure 332 may include sections located directly over the second portions 3052 of the second isolation structure 305. Each of the sections of the grid structure 332 may be formed around the perimeter of the corresponding one of the image sensing elements 306. The openings 332P of the grid structure 332 defined by the sections may be formed above the image sensing elements 306 to enable incident light to pass through the grid structure 332 and to the image sensing elements 306. The grid structure 332 may include suitable one or more light-shielding material(s) such as metallic material(s) or the like.

With continued reference to FIG. 6, the stacked IC device 10 may include light filter regions 334 overlying the dielectric layer 331 and corresponding to the openings 332P of the grid structure 332. For example, each of the light filter regions 334 is disposed directly above one of the openings 332P of the grid structure 332. The stacked IC device 10 may include micro-lenses 336 overlying the light filter regions 334 and configured to focus incident light towards the image sensing elements 306. For example, the stacked IC device 10 includes a plurality of pixel sensors PS1 arranged in an array and configured to receive photons of light from an upper side of the stacked IC device 10. The array of the pixel sensors PS1 may include the image sensing elements 306 which may absorb and accumulate photons of the incident light and may generate the photocurrent based on absorbed photons. In some embodiments, the stacked IC device 10 is an image sensor device, where the third IC tier 300 of the stacked IC device 10 is a sensor die configured to sense photons of incident light and convert the photons to a photocurrent, and the underlying second IC tier 200 and/or the first IC tier 100 may be viewed as a circuitry die configured to measure, manipulate, and/or otherwise use the photocurrent.

The stacked IC device 10 may include conductive pads 338 overlying the dielectric layer 331 and penetrating through the dielectric layer 331, the first portion 3051 of the second isolation structure 305, the third substrate 301, the first isolation structure 303, and the dielectric layers 312 of the third interconnect structure 310 to be in physical and electrical contact with the conductive patterns 314 of the third interconnect structure 310. For example, the conductive pads 338 are formed of one or more conductive material(s) such as aluminum, copper, silver, gold, some other conductive material, or any combination of the foregoing. In some embodiments, the respective conductive pad 338 includes an opening 338P to enable an external electrical connection to be formed to the conductive pad 338. In some embodiments, one or more conductive pads 338 are test pads for probe testing (e.g., a wafer acceptance test or the like). The above examples of the stacked IC device 10 are provided for illustrative purposes only, and other embodiments may utilize fewer or additional elements.

Still referring to FIG. 6, the second IC tier 200 of the stacked IC device 10 includes the TSV 230 penetrating through the third isolation structure 208. The third isolation structure 208 may serve as a stress-relief (or a buffer) layer. In this manner, the stress which arises from the fabrication of the TSV 230 or due to CTE mismatch between the TSV and the substrate may be reduced or minimized. The second IC tier 200 may be replaced with the second IC tiers (e.g., 200_1, 200_2, 200_3, 200_4, a combination thereof, etc.). As mentioned in FIGS. 3A-3D, by configuring the TSV 230 (or 230_1) and the associated stress-relief structure (e.g., the third isolation structure 208_1, the fourth isolation structure 208_2, the dummy device region 207_1D, and the dummy isolation structure 205″) in the middle tier of the stacked IC device 10, the impact of stress on the performance of the second IC tier may be reduced or minimized. As a result, the reliability of the stacked IC device 10 may be improved.

It is appreciated that in this written description, as well as in the claims below, the terms “first”, “second”, “third”, etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first IC tier” in the claims may not necessarily correspond to the “first IC tier” in the illustrated embodiment.

According to some embodiments, a device includes a first tier, and the first tier includes a first substrate including a first side, a second side opposite to the first side, and a sidewall connected to the first side and the second side, a first device disposed at the first side of the first substrate, a first isolation structure surrounding the first device, a second isolation structure disposed between the first isolation structure and the sidewall of the first substrate, a TSV extending between the first side and the second side of the first substrate, and a first bonding structure disposed over the first side of the first substrate and electrically coupled to the first device. The TSV is laterally separated from the first isolation structure by the second isolation structure.

According to some embodiments, a device includes a first tier, and the first tier includes a first substrate, an active device region disposed at a front side of the first substrate, a first isolation structure encircling the active device region, a second isolation structure disposed between the first isolation structure and an edge of the first substrate, a TSV penetrating through the first substrate, and a front-side bonding structure disposed over the front side of the first substrate and electrically coupled to the TSV and the active device region. The TSV and the second isolation structure being tapered in opposing directions.

According to some embodiments, a manufacturing method of a device includes providing a first tier. Providing the first tier includes: forming a first isolation structure, a second isolation structure, and a first device at a first side of a first substrate, where the first isolation structure surrounds the first device, and the second isolation structure is between the first isolation structure and a sidewall of the first substrate connected to the first side of the first substrate; forming a first bonding structure over the first side of the first substrate; and forming a TSV to pass through the first substrate, where the TSV is laterally separated from the first isolation structure by the second isolation structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first tier comprising:
a first substrate comprising a first side, a second side opposite to the first side, and a sidewall connected to the first side and the second side;
a first device disposed at the first side of the first substrate;
a first isolation structure surrounding the first device;
a second isolation structure disposed between the first isolation structure and the sidewall of the first substrate;
a through substrate via (TSV) extending between the first side and the second side of the first substrate, the TSV being laterally separated from the first isolation structure by the second isolation structure; and
a first bonding structure disposed over the first side of the first substrate and electrically coupled to the first device.

2. The device of claim 1, wherein the TSV penetrates through the second isolation structure.

3. The device of claim 1, wherein the first tier further comprises:
an interconnect structure disposed over the first side of the first substrate and electrically coupled to the first device, wherein the TSV comprises a first portion laterally connected to the first substrate, a second portion laterally connected to the interconnect structure, and a third portion connected to the first and second portions and laterally connected to the second isolation structure.

4. The device of claim 1, wherein the TSV is encircled by and laterally spaced apart from the second isolation structure.

5. The device of claim 4, wherein a portion of the first substrate laterally separates the TSV from the second isolation structure, and the portion of the first substrate comprises a lateral thickness on a sidewall of the TSV increases in a direction from the first side of the first substrate toward the second side of the first substrate.

6. The device of claim 1, wherein the first tier further comprises:
a dummy device surrounded by the second isolation structure, the TSV being laterally separated from the first device by the dummy device and the second isolation structure, and the dummy device being electrically floating in the first tier.

7. The device of claim 1, wherein the first tier further comprises:
a third isolation structure laterally interposed between the first and second isolation structures, the third isolation structure being tapered in the direction from the first side of the first substrate toward the second side of the first substrate.

8. The device of claim 1, further comprising:
a second tier bonded to the first tier, the second tier comprising:
a second substrate comprising a first side and a second side opposite to the first side;
a second device disposed at the first side of the second substrate;
a third bonding structure disposed over the first side of the second substrate and electrically coupled to the first device, the third bonding structure being bonded to a second bonding structure of the first tier, wherein the second bonding structure of the first tier is disposed below the second side of the first substrate and electrically coupled to the first device through the TSV.

9. The device of claim 8, wherein each of the second and third bonding structures comprises a bonding dielectric layer and bonding conductors laterally covered by the bonding dielectric layer, and a bonding surface of each of the second and third bonding structures is substantially flat.

10. The device of claim 8, further comprising:
a third tier bonded to the first tier, the third tier comprising:
a third substrate comprising a first side and a second side opposite to the first side;
a third device disposed at the first side of the third substrate;
an image sensing element disposed within the third substrate and coupled to the third device;
a fourth bonding structure disposed over the first side of the third substrate and electrically coupled to the third device, the fourth bonding structure being bonded to the first bonding structure of the first tier.

11. The device of claim 10, wherein the third tier comprises pixel sensors arranged in an array and comprising the image sensing element in the third substrate.

12. A device, comprising:
a first tier comprising:
a first substrate;
an active device region disposed at a front side of the first substrate;
a first isolation structure encircling the active device region;
a second isolation structure disposed between the first isolation structure and an edge of the first substrate;
a through substrate via (TSV) penetrating through the first substrate, the TSV and the second isolation structure being tapered in opposing directions; and
a front-side bonding structure disposed over the front side of the first substrate and electrically coupled to the TSV and the active device region.

13. The device of claim 12, wherein the second isolation structure is a close loop encircling the TSV in a top view.

14. The device of claim 12, wherein the TSV penetrates through the second isolation structure, and the second isolation structure extends further than the first isolation structure.

15. The device of claim 12, wherein the first tier further comprises:
a third isolation structure laterally between the first and second isolation structures and comprises a different top-view shape than the first isolation structure.

16. The device of claim 12, further comprising:
a second tier stacked upon and bonded to the first tier, the second tier comprising:
a second substrate comprising a first side and a second side opposite to the first side;
image sensing elements disposed between the first and second sides of the second substrate;
light filter regions disposed over the second side of the second substrate and directly over the image sensing elements; and
a bonding structure disposed below the first side of the second substrate and bonded to the front-side bonding structure of the first tier.

17. A manufacturing method of a device, comprising:
providing a first tier comprising:
forming a first isolation structure, a second isolation structure, and a first device at a first side of a first substrate, wherein the first isolation structure surrounds the first device, and the second isolation structure is between the first isolation structure and a sidewall of the first substrate connected to the first side of the first substrate;
forming a first bonding structure over the first side of the first substrate; and
forming a through substrate via (TSV) to pass through the first substrate, wherein the TSV is laterally separated from the first isolation structure by the second isolation structure.

18. The manufacturing method of claim 17, wherein the first and second isolation structures are formed at a same step.

19. The manufacturing method of claim 17, wherein providing the first tier further comprises:
performing a planarization process on the first bonding structure, wherein the first bonding structure comprises a bonding dielectric layer and bonding conductors laterally covered by the bonding dielectric layer.

20. The manufacturing method of claim 17, further comprising:
providing a second tier, wherein the second tier comprises:
a second substrate comprising a first side and a second side opposite to the first side;
image sensing elements formed between the first and second sides of the second substrate;
light filter regions formed over the second side of the second substrate and corresponding to the image sensing elements; and
a second bonding structure formed over the first side of the second substrate; and
bonding the second tier to the first tier, where the second bonding structure of the second tier is bonded to the first bonding structure of the first tier.
